(19) United States
(12) Patent Application Publication
(10) Pub. No.: US 2020/0225573 A1
(43) Pub. Date: Jul. 16, 2020

(54) PELLICLE MEMBER AND RETICLE ASSEMBLY INCLUDING THE SAME

(71) Applicant: SAMSUNG ELECTRONICS CO., LTD., Suwon-si (KR)

(72) Inventors: Jong Keun OH, Seoul (KR); Jin-Sang YOON, Suwon-si (KR); Byungchul YOO, Yongin-si (KR); Sunpyo LEE, Hwaseong-si (KR); Changyoung JEONG, Yongin-si (KR)

(73) Assignee: SAMSUNG ELECTRONICS CO., LTD., Suwon-si (KR)

(21) Appl. No.: 16/541,895

(22) Filed: Aug. 15, 2019

(30) Foreign Application Priority Data
Jan. 14, 2019 (KR) 10-2019-0004645

(51) Int. Cl. G03F 1/64; G03F 7/20

(52) U.S. Cl. CPC G03F 1/64; G03F 7/70983

(57) ABSTRACT

A reticle assembly includes a reticle plate; a reticle pattern provided on the reticle plate; and a pellicle member provided on the reticle pattern and the reticle plate. The pellicle member includes: a pellicle provided on the reticle pattern; and a pellicle frame provided on the reticle plate and surrounding the reticle pattern, and supporting the pellicle to be space apart from the reticle pattern and the reticle plate. A thermal expansion coefficient of the pellicle frame is less than six times of a thermal expansion coefficient of the reticle plate

### CROSS-REFERENCE TO RELATED APPLICATION

This application claims priority under 35 U.S.C § 119 to Korean Patent Application No. 10-2019-0004645 filed on Jan. 14, 2019 in the Korean Intellectual Property Office, the entire contents of which are hereby incorporated by reference.

### BACKGROUND

Apparatuses consistent with example embodiments relate to an apparatus for fabricating a semiconductor device, and more particularly, to a pellicle member of a reticle assembly for protecting a reticle pattern of the reticle assembly.

Semiconductor devices have recently been designed such that critical dimension (CD) of the semiconductor devices is reduced. In the field of semiconductor devices, the CD is defined as the size of a feature on an integrated circuit or transistor that impacts the electrical properties of the semiconductor devices.

The CD of the semiconductor devices may be determined through an exposure apparatus used for photolithography. For example, the exposure apparatus may include a light source, a reticle assembly, and an optical system. The reticle assembly including a reticle pattern may be vulnerable to particle contamination, and to minimize such possible contamination of the reticle pattern, the reticle assembly includes a pellicle member for the purpose of minimizing potential contamination due to foreign material being placed on the reticle pattern.

### SUMMARY

One or more example embodiments provide a reticle assembly capable of minimizing exposure deformation defects.

According to an aspect of an example embodiment, there is provided a reticle assembly including: a reticle plate; a reticle pattern provided on the reticle plate; and a pellicle member provided on the reticle pattern and the reticle plate. The pellicle member includes: a pellicle provided on the reticle pattern; and a pellicle frame provided on the reticle plate and surrounding the reticle pattern, and supporting the pellicle to be spaced apart the reticle pattern and the reticle plate. A thermal expansion coefficient of the pellicle frame is less than six times of a thermal expansion coefficient of the reticle plate.

According to an aspect of another example embodiment, there is provided a pellicle member including: a pellicle; and a pellicle frame provided on an edge of the pellicle. A thermal expansion coefficient of the pellicle frame is within a range of between 1.0×10⁻⁶/K and 1.0×10⁻⁵/k.

According to an aspect of another example embodiment, there is provided a pellicle member including: a pellicle; and a pellicle frame provided on an edge of the pellicle. The pellicle frame may include an iron-nickel alloy.

### BRIEF DESCRIPTION OF THE DRAWINGS

FIG. 1 illustrates an exploded perspective view a reticle assembly according to an example embodiment.

FIG. 2 illustrates a cross-sectional view of a reticle assembly according to an example embodiment.

FIG. 3 illustrates a graph showing a relationship between the occurrence of exposure deformation defects and the thermal expansion coefficient of a pellicle frame shown in FIGS. 1 and 2.

### DETAILED DESCRIPTION

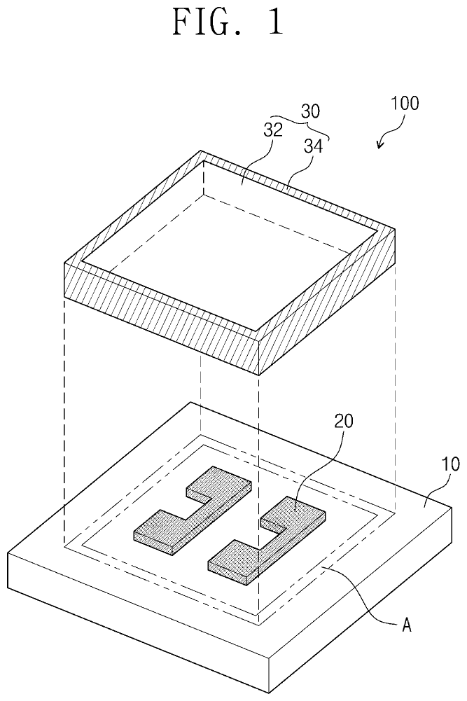

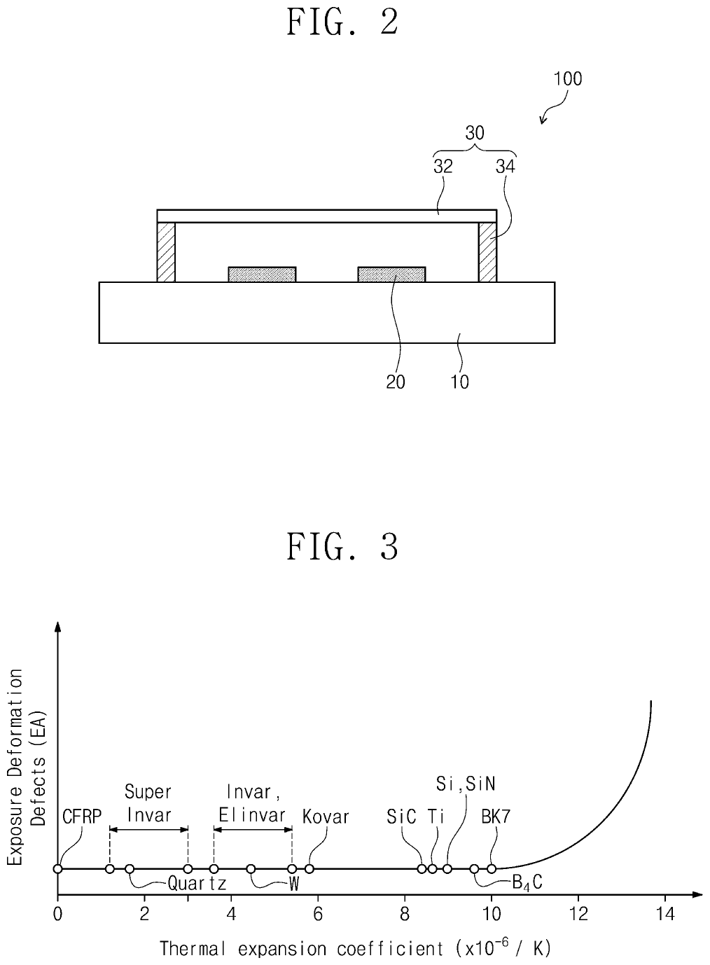

FIG. 1 illustrates an exploded view and a cross-sectional view of a reticle assembly 100 according to an example embodiment. FIG. 2 illustrates a cross-sectional view of a reticle assembly according to an example embodiment.

Referring to FIGS. 1 and 2, the reticle assembly 100 may be a photomask. For example, the reticle assembly 100 may include a reticle plate 10, a reticle pattern 20, and a pellicle member 30.

The reticle plate 10 may be a hexahedral plate and may be transparent. The reticle plate 10 may include quartz. The reticle plate 10 may have a thermal expansion coefficient (also known as CTE) of, for example, about 1.77×10⁻⁶/K or about 1.77×10⁻⁶/° C. Here, the thermal expansion coefficient may be a volumetric thermal expansion coefficient, and its units “/K” and “/° C.” may be the same. The reticle plate 10 may have a top surface where an area of the top surface falls within a range of about 23,000 mm³ to about 23,500 mm³. The area of the top surface of the reticle plate 10 may mainly depend on a numerical aperture (NA) of an object lens included in the exposure apparatus. The numerical aperture of the object lens is a measure of its ability to gather light and resolve fine specimen detail at a fixed object distance.

The reticle pattern 20 may be disposed on a central region of the reticle plate 10. The reticle pattern 20 may absorb light radiated to the reticle plate 10. The reticle pattern 20 may include, for example, chromium (Cr).

The pellicle member 30 may be disposed on the reticle plate 10 and the reticle pattern 20. The pellicle member 30 may be incorporated as a dustproof component for protecting the reticle pattern 20 against particles. The pellicle member 30 may include a pellicle 32 and a pellicle frame 34 supporting the pellicle 32.

The pellicle 32 may be provided on the reticle pattern 20. The pellicle 32 may be a transparent film or membrane. The pellicle 32 may include a carbon compound film. For example, the pellicle 32 may include nitrocellulose. The pellicle 32 may have an area less than an area of the top surface of the reticle plate 10 and greater than an area of the reticle pattern 20.

The pellicle frame 34 may be disposed between the pellicle 32 and the reticle plate 10. The pellicle frame 34 may support the pellicle 32 so that the pellicle 32 is spaced apart from the reticle pattern 20. The pellicle frame 34 may surround a counter of the reticle pattern 20 and may have a rectangular ring shape. The pellicle frame 34 may be attached through an adhesive to the reticle plate 10. The pellicle frame 34 may rigidly place the pellicle 32 on the reticle plate 10.

The pellicle frame 34 may have a bottom surface where an area of the bottom surface corresponds to a contact area A between the pellicle frame 34 and the reticle plate 10. Thermal deformation of the pellicle frame 34 may cause exposure deformation defects of the reticle plate 10. The exposure deformation defects of the reticle plate 10 may be reduced depending on the contact area A. The contact area A may be, for example, about 705 mm³ to about 1,150 mm³. A contact area ratio of the pellicle frame 34 to the reticle plate 10 may be in a range from about 3% to about 5%. For example, the bottom surface of the pellicle frame 34 may have an area of about 3% to about 5% of an overall top surface area of the reticle plate 10. When the bottom surface area of the pellicle frame 34 is greater than about 5% of the overall top surface area of the reticle plate 10, the reticle plate 10 may increase in exposure deformation defects. When the bottom surface area of the pellicle frame 34 is less than about 3% of the overall top surface area of the reticle plate 10, the reticle plate 10 and the pellicle frame 34 may suffer from contact failure and/or fixing defects therebetween.

The exposure deformation defects of the reticle plate 10 may be caused by a difference in thermal expansion coefficient between the pellicle frame 34 and the reticle plate 10. For example, the pellicle frame 34 may have a thermal expansion coefficient the same as or similar to that of the reticle plate 10. The thermal expansion coefficient of the pellicle frame 34 may be about six times greater than the thermal expansion coefficient of the reticle plate 10. For example, the thermal expansion coefficient of the pellicle frame 34 may be less than about 1.0×10⁻⁵/K.

FIG. 3 illustrates a graph showing a relationship between the occurrence of exposure deformation defects and the thermal expansion coefficient of a pellicle frame shown in FIGS. 1 and 2.

Referring to FIG. 3, when the pellicle frame 34 has a thermal expansion coefficient less than about 1.0×10⁻⁵/K, the occurrence of exposure deformation defects may be minimized or maximally suppressed.

In example embodiments, the pellicle frame 34 may include an iron-nickel alloy. The iron-nickel alloy may facilitate production of the pellicle frame 34. The pellicle frame 34 of the iron-nickel alloy may have a thermal expansion coefficient of about 1.2×10⁻⁶/K to about 5.8×10⁻⁶/K. For example, the pellicle frame 34 may include 63Fe-32NI-5Co known as Super Invar 32-5, 64Fe-36Ni known as Invar, 52Fe-36Ni-12Cr known as Elinvar, or 53Fe-29Ni-17Co known as Kovar.

Super Invar may have a thermal expansion coefficient of about 1.2×10⁻⁶/K to about 3.0×10⁻⁶/K. The pellicle frame 34 of Super Invar may have the same thermal expansion coefficient as that of the reticle plate 10 of quartz at temperatures between about 25° C. and about 100° C. When the pellicle frame 34 includes Super Invar and the reticle plate 10 includes quartz, a difference in thermal expansion coefficient between the pellicle frame 34 and the reticle plate 10 may be eliminated to prevent or minimize the exposure deformation defects.

Invar may have a thermal expansion coefficient of about 3.6×10⁻⁶/K to about 5.4.0×10⁻⁶/K. For example, Invar may have a thermal expansion coefficient of about 3.6×10⁻⁶/K at temperatures between about −17.8° C. to about 25° C., and about 5.4×10⁻⁶/K or less at temperatures between about 25° C. to about 145° C.

Elinvar may have a thermal expansion coefficient that is the same as or similar to a thermal expansion coefficient of Invar. Elinvar may be a metal alloy having an elastic coefficient that does not change with a change in temperature.

Kovar may have a thermal expansion coefficient that is the same as a thermal expansion coefficient of a hard glass. Kovar may have a thermal expansion coefficient of about 5.8×10⁻⁶/K.

In other example embodiments, the pellicle frame 34 may include nonferrous metal. The pellicle frame 34 of nonferrous metal may have a thermal expansion coefficient of about 4.5×10⁻⁶/K to about 8.6×10⁻⁶/K. For example, the pellicle frame 34 may include tungsten (W) or titanium (Ti). Tungsten (W) may have a thermal expansion coefficient of about 4.5×10⁻⁶/K. Titanium (Ti) may have a thermal expansion coefficient of about 8.6×10⁻⁶/K.

In other example embodiments, the pellicle frame 34 may include carbide. The pellicle frame 34 made of carbide may have a thermal expansion coefficient of about 8.3×10⁻⁶/K to about 9.6×10⁻⁶/K. For example, the carbide of the pellicle frame 34 may include one or more of silicon carbide (SiC) and boron carbide (B₄C). Silicon carbide (SiC) may have a thermal expansion coefficient of about 8.3×10⁻⁶/K. Boron carbide (B₄C) may have a thermal expansion coefficient of about 9.6×10⁻⁶/K.

In other example embodiments, the pellicle frame 34 may include silicon (Si) or silicon compounds (e.g., silicon oxide, silicon nitride, or silicate). The pellicle frame 34 may have a thermal expansion coefficient of about 1.77×10⁻⁶/K to about 9.9×10⁻⁶/K. For example, the Si or the silicon compounds of the pellicle frame 34 may include one or more of quartz, silicon nitride (SiN), and borosilicate glass (BK7). Quartz may have a thermal expansion coefficient of about 1.77×10⁻⁶/K. When the pellicle frame 34 and the reticle plate 10 include quartz, the occurrence of exposure deformation defects may be prevented or minimized. Silicon (Si) and silicon nitride (SiN) may have a thermal expansion coefficient of about 9.0×10⁻⁶/K. Borosilicate glass (BK7) may have a thermal expansion coefficient of about 9.9×10⁻⁶/K.

In other example embodiments, the pellicle frame 34 may include a carbon fiber reinforced polymer (CFRP). The CFRP may have a thermal expansion coefficient of almost zero. When the pellicle frame 34 includes a CFRP and the reticle plate 10 includes quartz, a difference in thermal expansion coefficient between the pellicle frame 34 and the reticle plate 10 may be decreased to reduce the occurrence of exposure deformation defects.

According to the example embodiments described above, a reticle assembly may include a pellicle frame having a thermal expansion coefficient being the same as or similar to that of a reticle plate, thereby resulting in minimization of exposure deformation defects.

While example embodiments have been shown and described above, it will be apparent to those skilled in the art that modifications and variations could be made without departing from the scope of the present inventive concept as defined by the appended claims.

What is claimed is:

1. A reticle assembly comprising:
a reticle plate;
a reticle pattern provided on the reticle plate; and
a pellicle member provided on the reticle pattern and the reticle plate,
wherein the pellicle member comprises:
a pellicle provided on the reticle pattern; and
a pellicle frame provided on the reticle plate and surrounding the reticle pattern, the pellicle frame supporting the pellicle to be spaced apart from the reticle pattern and the reticle plate, and
wherein a thermal expansion coefficient of the pellicle frame is less than six times of a thermal expansion coefficient of the reticle plate.

2. The reticle assembly of claim 1, wherein the thermal expansion coefficient of the reticle plate is 1.77×10⁻⁶/K, and
the thermal expansion coefficient of the pellicle frame is less than 1.0×10⁻⁵/K.

3. The reticle assembly of claim 2, wherein the pellicle frame comprises an iron-nickel alloy.

4. The reticle assembly of claim 3, wherein the iron-nickel alloy of the pellicle frame is Super Invar 32-5, Invar, Elinvar, or Kovar.

5. The reticle assembly of claim 2, wherein the pellicle frame comprises nonferrous metal.

6. The reticle assembly of claim 5, wherein the nonferrous metal of the pellicle frame is tungsten or titanium.

7. The reticle assembly of claim 2, wherein the pellicle frame comprises carbide.

8. The reticle assembly of claim 7, wherein the carbide of the pellicle frame is silicon carbide or boron carbide.

9. The reticle assembly of claim 2, wherein the pellicle frame comprises silicon or silicon compound.

10. The reticle assembly of claim 9, wherein the silicon or silicon compound of the pellicle frame is quartz, silicon nitride, or borosilicate glass.

11. The reticle assembly of claim 2, wherein the pellicle frame comprises a carbon fiber reinforced polymer.

12. The reticle assembly of claim 1, wherein the pellicle frame has a first surface contacting a second surface the reticle plate, and
a first area of the first surface of the pellicle frame area is within a range of 3% to 5% of a second area of the second surface of the reticle plate.

13. A pellicle member comprising:
a pellicle; and
a pellicle frame provided on an edge of the pellicle,
wherein a thermal expansion coefficient of the pellicle frame is within a range of between 1.0×10⁻⁶/K to 1.0×10⁻⁵/k.

14. The pellicle member of claim 13, wherein the pellicle frame comprises Super Invar 32-5, Invar, Elinvar, or Kovar.

15. The pellicle member of claim 13, wherein the pellicle frame comprises tungsten or titanium.

16. The pellicle member of claim 13, wherein the pellicle frame comprises silicon carbide, boron carbide, quartz, silicon nitride, or borosilicate glass.

17. A pellicle member, comprising:
a pellicle; and
a pellicle frame provided on an edge of the pellicle,
wherein the pellicle frame comprises an iron-nickel alloy.

18. The pellicle member of claim 17, wherein the iron-nickel alloy of the pellicle frame is Super Invar 32-5.

19. The pellicle member of claim 17, wherein the iron-nickel alloy of the pellicle frame is Invar or Elinvar.

20. The pellicle member of claim 17, wherein the iron-nickel alloy of the pellicle frame is Kovar.
